(19) United States
(12) Patent Application Publication
(10) Pub. No.: US 2011/0277807 A1
(43) Pub. Date: Nov. 17, 2011

(54) PHOTOELECTRIC CONVERSION MODULE

(76) Inventor: Nam-Choul Yang, Yongin-si (KR)

(21) Appl. No.: 12/946,746

(22) Filed: Nov. 15, 2010

Related U.S. Application Data
(60) Provisional application No. 61/334,989, filed on May 14, 2010.

(51) Int. Cl. H01L 31/042; H01L 21/04

(52) U.S. Cl. 136/244; 438/57; 257/E21.04

(57) ABSTRACT

A photoelectric conversion module including an electrolyte inlet allowing an electrolyte to be introduced to at least two neighboring photoelectric cells simultaneously, reducing the number of electrolyte inlets needed to fill photoelectric cells.

### CROSS-REFERENCE TO RELATED APPLICATION

This application claims the benefit of U.S. Provisional Application No. 61/334,989, filed on May 14, 2010, in the United States Patent and Trademark Office, the entire content of which is incorporated herein by reference.

### BACKGROUND

1. Field

This description relates to a photoelectric conversion module for converting solar energy into electric energy.

2. Description of the Related Art

Recently, solar energy has received considerable attention as a renewable energy for replacing petroleum, coal, and natural gas. Solar cells may be silicon solar cells or compound semiconductor solar cells, which differ according to the material used to form the solar cell. Monocrystalline and polycrystalline silicon solar cells, amorphous silicon solar cells, and others have been widely used and sold. Silicon solar cells use semiconductor materials, and are based on the photoelectric conversion principle.

A dye-sensitized solar cell (DSSC) is a solar cell based on a photoelectrochemical conversion mechanism using photosynthesis. Since a DSSC has a higher theoretical limitation conversion efficiency than that of a typical silicon solar cell, there are more opportunities for increasing the conversion efficiency of a DSSC, and manufacturing costs of a DSSC may be ⅕ that of a typical silicon solar cell. In addition, DSSCs are expected to be highly developed due to their wide applicability.

When a DSSC absorbs sunlight, electrons in dye molecules are excited, and the electrons are injected into a conduction band of a semiconductor oxide. The injected electrons move to a conductive film through a grain boundary between particles of an oxide electrode, and holes formed in the dye molecules are reduced by an electrolyte contained between opposites substrates sealed by a sealer, thereby generating a current.

### SUMMARY

An aspect of an embodiment of the present invention is directed toward a photoelectric conversion module including electrolyte inlets for injecting an electrolyte into a plurality of unit cells, where the number of the electrolyte inlets is reduced so as to improve durability and manufacturing yield and to reduce manufacturing costs.

According to an exemplary embodiment of the present invention, a photoelectric conversion module includes a first photoelectric cell and a second photoelectric cell, each of the photoelectric cells comprising a photoelectrode, a counter electrode facing the photoelectrode, and a semiconductor layer on the photoelectrode and onto which a photosensitive dye is adsorbed. The photoelectric conversion module also includes a first sealing member extending along a first direction between the first photoelectric cell and the second photoelectric cell, the first sealing member defining a first via between the first photoelectric cell and the second photoelectric cell.

The photoelectric conversion may further include a conduit, the conduit corresponding and adjacent to the first via. The photoelectric conversion module of may further include a filler in the conduit to seal the conduit. The photoelectric conversion module may further include a cap adjacent to the filler and configured to form a double sealing structure to seal the conduit.

The photoelectric conversion module may further include a first substrate and a second substrate, the first and second photoelectric cells being between the first substrate and the second substrate, wherein the conduit extends through one of the first substrate or the second substrate along a second direction crossing the first direction.

The photoelectric conversion module may further include a sealing frame surrounding the photoelectric cells, wherein the conduit extends through the sealing frame to communicate with the first via. The first via may be at a first end of the first and second photoelectric cells, the first sealing member may define a second via at a second end of the first and second photoelectric cells, the first conduit may be at the first end of the first and second photoelectric cells and a second conduit may be at a second end of the first and second photoelectric cells corresponding and adjacent to the second via.

The photoelectric conversion module may further include a third photoelectric cell and a second sealing member extending along the first direction between the second photoelectric cell and the third photoelectric cell, the second sealing member defining a second via between the second photoelectric cell and the third photoelectric cell. The photoelectric conversion module may further include a conduit corresponding and adjacent to the first and second vias.

The photoelectric conversion module may further include a filler in the first via, the filler configured to physically block the first photoelectric cell from the second photoelectric cell. The photoelectric conversion module may further include a cap adjacent to the filler and configured to seal the solar cell. The filler and the cap may be configured to physically block the first conduit.

An aspect of an embodiment of the present invention is directed toward a method of forming a photoelectric conversion module. The method includes forming a photoelectrode on a first substrate, forming a semiconductor layer on the photoelectrode, adsorbing a photosensitive dye on the semiconductor layer, forming an electrode on a second substrate, forming a catalyst layer on the electrode, providing a sealing member extending along a first direction between a first photoelectric cell and a second photoelectric cell, providing a via in the sealing member between the first photoelectric cell and the second photoelectric cell, adhering the first substrate to the second substrate, providing a conduit to correspond and be adjacent to the via, filling the first photoelectric cell and second photoelectric cell with an electrolyte through the conduit and the via, providing a filler in the via to physically block the first photoelectric cell from the second photoelectric cell, and sealing the conduit.

The sealing the conduit may include providing the filler to fill the conduit. The sealing the conduit may also include providing a cap and affixing the cap over the conduit. The affixing of the cap may include providing an adhering agent to adhere the cap over the conduit. The providing of the conduit may include forming the conduit in the first substrate or the second substrate to extend along a second direction crossing the first direction. The providing of the via in the sealing member may include forming the via through the sealing member along a third direction crossing the first direction and the second direction.

The method of forming the photoelectric conversion module may further include forming a sealing frame to surround the photoelectric cells, wherein the providing of the conduit may include forming the conduit through the sealing frame to communicate with the via. The providing of the via may include providing a first via at a first end of the first and second photoelectric cells and providing a second via at a second end of the first and second photoelectric cells, and the proving of the conduit may include providing a first conduit at the first end of the first and second photoelectric cells and providing a second conduit at the second end of the first and second photoelectric cells, the second conduit corresponding and adjacent to the second via.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a plan view of a photoelectric conversion module according to an embodiment of the present invention;

FIG. 2 is a cross-sectional view of the photoelectric conversion module of FIG. 1 taken along a line II-II′ of FIG. 1;

FIG. 3 is an exploded perspective view of a photoelectric conversion module according to an embodiment of the present invention;

FIG. 4 is a schematic plan view showing spreading directions of an electrolyte that is injected through electrolyte inlets of a photoelectric conversion module, according to an embodiment of the present invention;

FIG. 5 is a cross-sectional view of the photoelectric conversion module of FIG. 3 taken along a line V-V′ of FIG. 3;

FIG. 6 is an exploded perspective view of a photoelectric conversion module according to another embodiment of the present invention;

FIG. 7 is an exploded perspective view of a photoelectric conversion module according to a modified embodiment of FIG. 6;

FIG. 8 is a plan view showing a case where electrolyte inlets of the photoelectric conversion module of FIG. 6 are sealed, according to an embodiment of the present invention;

FIG. 9 is a schematic plan view showing spreading directions of an electrolyte that is injected through electrolyte inlets of a photoelectric conversion module, according to yet another embodiment of the present invention;

FIG. 10 is a plan view showing a case where an electrolyte inlet and a via are sealed in the photoelectric conversion module of FIG. 9; and

FIG. 11 is a flow chart showing a method of manufacturing a photoelectric conversion module, according to embodiments of the present invention.

### DETAILED DESCRIPTION

Hereinafter, exemplary embodiments of the present invention will be described in detail with reference to the accompanying drawings such that those having ordinary skill in the art to which the present invention pertains may implement the technological concept of the present invention. However, the present invention may be implemented in various different ways, and is not limited to the following exemplary embodiments. Like reference numerals designate like constituent elements throughout the specification.

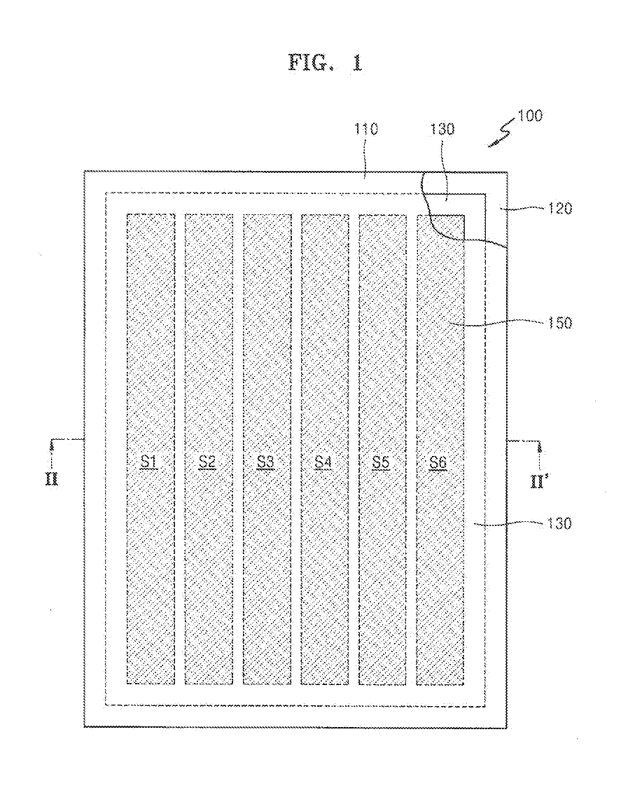

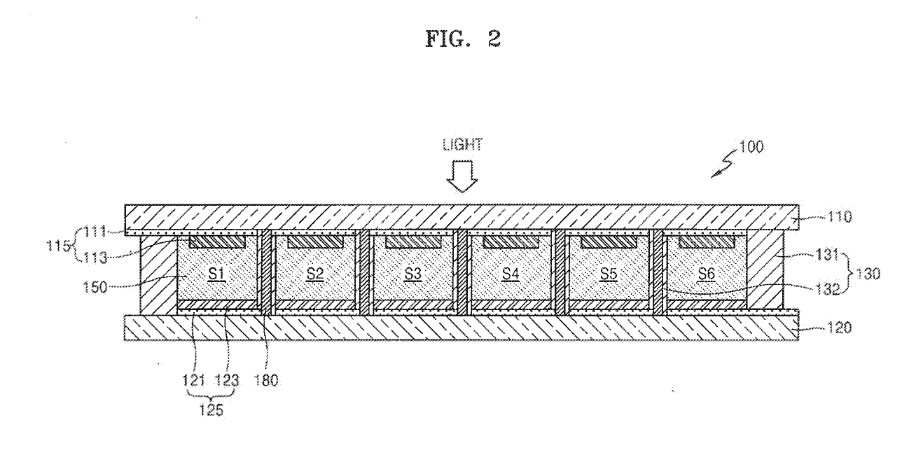

FIG. 1 is a plan view of a photoelectric conversion module 100 according to an embodiment of the present invention. FIG. 2 is a cross-sectional view of the photoelectric conversion module 100 taken along the line of FIG. 1.

Referring to FIGS. 1 and 2, the photoelectric conversion module 100 includes a plurality of photoelectric cells S1, S2, S3, S4, S5, and S6. The photoelectric cells S1, S2, S3, S4, S5, and S6 are separated by sealing members 130.

The photoelectric cells S1, S2, S3, S4, S5, and S6 are respectively filled with an electrolyte 150. The electrolyte 150 filled in the photoelectric cells S1, S2, S3, S4, S5, and S6 is injected through an electrolyte inlet. After the photoelectric cells S1, S2, S3, S4, S5, and S6 are filled, the electrolyte inlet is sealed, thus keeping the electrolyte 150 from leaking out of the photoelectric cells S1, S2, S3, S4, S5, and S6.

Referring to FIG. 2, the photoelectric conversion module 100 includes a light receiving substrate 110 and an opposite substrate 120 that face each other. The photoelectric cells S1, S2, S3, S4, S5, and S6, which are separated from each other by the sealing members 130, are formed between the light receiving substrate 110 and the opposite substrate 120.

A photoelectrode 111 and an opposite electrode 121 are formed on the light receiving substrate 110 and the opposite substrate 120, respectively. The light receiving substrate 110 and the opposite substrate 120 are disposed a predetermined interval away from each other (i.e., they are spaced apart) by interposing sealing members 130 between the light receiving substrate 110 and the opposite substrate 120. A semiconductor oxide layer 113 (onto which photosensitive dye that may be excited by light is adsorbed) is formed on the photoelectrode 111. The electrolyte 150 is filled between the semiconductor oxide layer 113 and the opposite electrode 121.

The light receiving substrate 110 may be formed of a transparent material, for example, a material having a relatively high light transmittance. For example, the light receiving substrate 110 may be a glass or resin substrate formed of glass or a resin film. Since a resin film is usually flexible, a resin film light receiving substrate 110 may be used to achieve flexibility.

The photoelectrode 111 functions as a negative electrode of the photoelectric conversion module 100, and is part of a current path that receives electrons generated by photoelectric conversion. The photoelectrode 111 may be formed of a transparent conducting oxide (TCO) having a relatively high electrical conductivity and a relatively high optical transparency, such as indium tin oxide (ITO), fluorine-doped tin oxide (FTO), or antimony tin oxide (ATO). The photoelectrode 111 may further include a metal electrode formed of metal having relatively high electrical conductivity, such as gold (Ag), silver (Au), or aluminum (Al). The metal electrode is included to reduce the electric resistance of the photoelectrode 111, and may be formed on the TCO in a stripe pattern or a mesh pattern.

The semiconductor oxide layer 113 may be formed of a semiconductor, for example, a metal oxide including cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si), or chromium (Cr). The semiconductor oxide layer 113 adsorbs a photosensitive dye to increase its photoelectric conversion efficiency. For example, the semiconductor oxide layer 113 may be formed by coating a paste having semiconductor particles, each having a diameter at or between 5 nm and 1000 nm (or ranging from 5 nm to 1000 nm), on the photoelectrode 111 and then heating or pressing the paste.

The photosensitive dye adsorbed onto the semiconductor oxide layer 113 absorbs light transmitted through the light receiving substrate 110. When light is absorbed by the photosensitive dye, electrons of the photosensitive dye are excited from a ground state to an excitation state. The excited electrons move to a conduction band of the semiconductor oxide layer 113, then move to the photoelectrode 111, and then are extracted out of the photoelectric conversion module 100 through the photoelectrode 111, producing a driving current for driving an external circuit.

For example, the photosensitive dye adsorbed onto the semiconductor oxide layer 113 includes a molecule that absorbs visible light and causes electrons in a light excitation state to quickly move to the semiconductor oxide layer 113. The photosensitive dye may be in a liquid state, a semi-liquid gel state, or a solid state. For example, the photosensitive dye adsorbed onto the semiconductor oxide layer 113 may be a ruthenium-based photosensitive dye. The light receiving substrate 110 and semiconductor oxide layer 113 may be immersed in a solution including a photosensitive dye to obtain the semiconductor oxide layer 113 onto which photosensitive dye is adsorbed.

The electrolyte 150 may be a redox electrolyte including an oxidizer and reducer pair. The electrolyte 150 may also be a solid-type electrolyte, a gel-type electrolyte, or a liquid-type electrolyte.

The opposite substrate 120 facing the light receiving substrate 110 does not have to be transparent. However, the opposite substrate 120 may be formed of a transparent material so as to increase its photoelectric conversion efficiency, and may be formed of the same material as the light receiving substrate 110. In particular, when the photoelectric conversion module 100 is used as a building integrated photovoltaic (BIPV) system, in a structure such as a window frame, both sides of the photoelectric conversion module 100 may be transparent so as to allow light to transfer to the interior of the building. For example, the opposite electrode 121 may be formed of a TCO having a relatively high electrical conductivity and (a relatively high) optical transparency, such as ITO, FTO, or ATO. The opposite electrode 121 may further include a metal electrode formed of a metal having relatively high electrical conductivity, such as Ag, Au, or Al. The metal electrode is included to decrease the electric resistance of the opposite electrode 121, and may be formed on the TOO in a stripe pattern or a mesh pattern.

The opposite electrode 121 functions as the positive electrode of the photoelectric conversion module 100. Electrons excited by light emitted through the light receiving substrate 110 or the other substrate 120 are extracted out of the photoelectric conversion module 100 through the photoelectrode 111. The photosensitive dye, which loses electrons that are excited by light, is then reduced as it receives electrons provided by oxidation of the electrolyte 150. The oxidized electrolyte 150 is reduced as it receives electrons that have reached the opposite electrode 121 through an external circuit, thereby completing the photoelectric conversion.

A catalyst layer 123 may be formed on the opposite electrode 121. The catalyst layer 123 may be formed of a material that functions as a reduction catalyst for providing electrons, and may be formed of a metal such as platinum (Pt), silver (Ag), gold (Au), copper (Cu), or aluminum (Al), a metal oxide such as tin oxide, or a carbon-based material such as graphite.

Adhesive members 180 are disposed between the photoelectric cells S1, S2, S3, S4, S5, and S6 so as to adhere and seal the photoelectric cells S1, S2, S3, S4, S5, and S6 to each other. Referring to FIG. 2, the photoelectric cells S1, S2, S3, S4, S5, and S6 are adhered in parallel to each other by the adhesive members 180. The adhesive members 180 may be formed between the sealing members 130. The adhesive members 180 may vertically extend so as to contact the photoelectrode 111 and the opposite electrode 121 respectively disposed at upper and lower locations, and may connect a plurality of the photoelectrodes 111 and a plurality of the opposite electrodes 121 that are disposed between the photoelectric cells S1, S2, S3, S4, S5, and S6 in parallel. The adhesive members 180 may be formed of a metal material having an excellent conductivity. For example, the adhesive members 180 are formed by filling a conductive paste into an accommodation space defined by the sealing members 130.

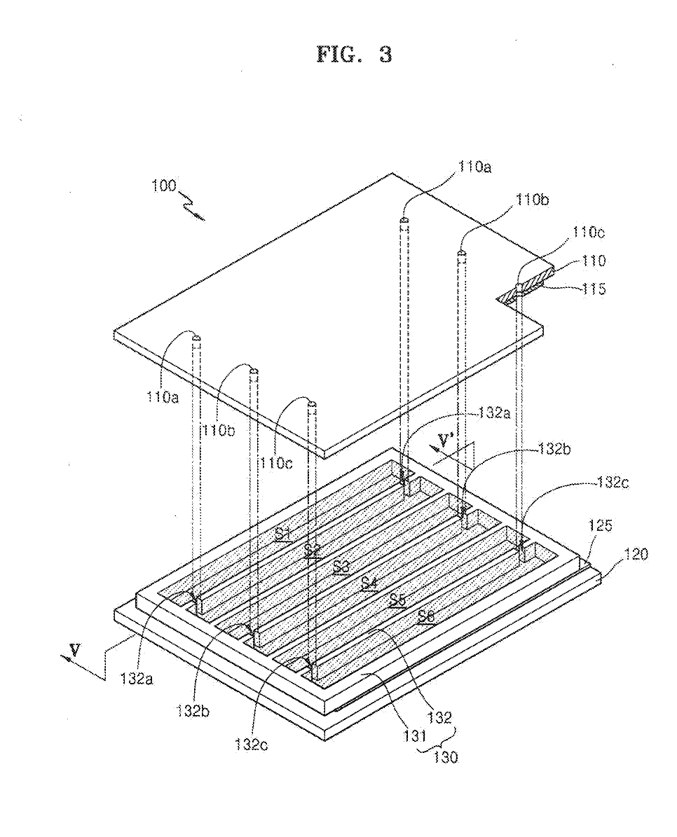

FIG. 3 is an exploded perspective view of a photoelectric conversion module 100 according to an embodiment of the present invention. Referring to FIG. 3, electrolyte inlets 110a, 110b, and 110c (i.e., electrolyte conduits or conduits) are formed respectively between every other neighboring photoelectric cells (for example, electrolyte inlet 110a is formed between S1 and S2, and electrolyte inlet 110b is formed between S3 and S4). The electrolyte inlets 110a, 110b, and 110c may be formed to correspond to the sealing members 132. For example, electrolyte inlet 110a may be formed to correspond to the sealing member 132 separating neighboring photoelectric cells S1 and S2. Portions of the sealing members 132 corresponding to the electrolyte inlets 110a, 110b, and 110c may be open so that a fluid may flow between the neighboring photoelectric cells S1 and S2, S3 and S4, and S5 and S6. Thus, only six electrolyte inlets 110a, 110b, and 110c are formed for six photoelectric cells. According to the present embodiment, the number of electrolyte inlets may be half the number of electrolyte inlets in a Comparative Example, wherein 12 electrolyte inlets are respectively in photoelectric cells (two electrolyte inlets for each cell).

In FIG. 3, the electrolyte inlets 110a, 110b, and 110c are each disposed at both ends of the photoelectric cells S1, S2, S3, S4, S5, and S6, but the present embodiment is not limited thereto. In some embodiments, the electrolyte inlets 110a, 110b, and 110c may each be disposed at only one end of the photoelectric cells S1, S2, S3, S4, S5, or S6. In this case, since three electrolyte inlets are formed for six photoelectric cells, the number of electrolyte inlets is half the number of electrolyte inlets in Comparative Example, wherein 6 electrolyte inlets are respectively formed in photoelectric cells (one electrolyte inlet for each cell).

In FIG. 3, the electrolyte inlets 110a, 110b, and 110c are formed in the light receiving substrate 110. However, the electrolyte inlets 110a, 110b, and 110c may be formed in other surfaces. For instance, the electrolyte inlets 110a, 110b, and 110c may be formed in the opposite substrate 120.

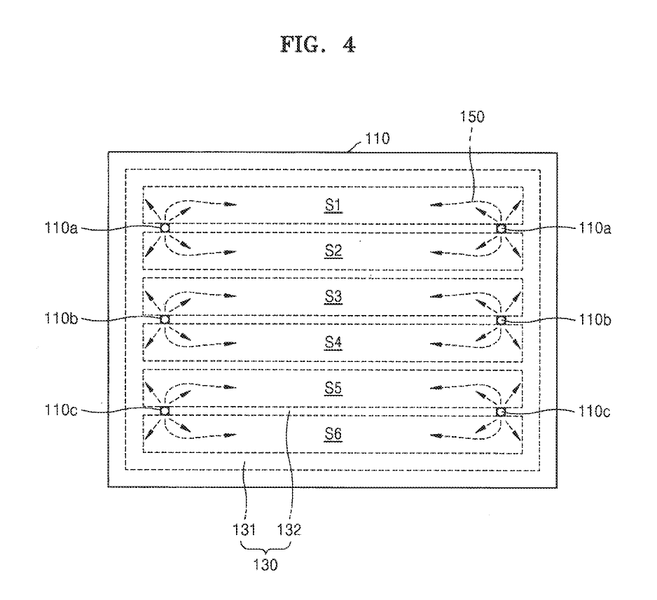

FIG. 4 is a schematic plan view showing spreading directions of the electrolyte 150 injected through the electrolyte inlets 110a, 11013, and 110c in the photoelectric conversion module 100, according to an embodiment of the present invention. Referring to FIG. 4, the electrolyte 150 injected through an electrolyte inlet 110a that is positioned between S1 and S2 may move to the photoelectric cell S2 as well as to the photoelectric cell S1. Therefore, according to the present embodiment, even if the number of the electrolyte inlets 110a, 110b, and 110c is half the number of electrolyte inlets in a Comparative Example, electrolyte may still be inserted into each of the photoelectric cells.

After injection of the electrolyte, the electrolyte inlets 110a, 110b and 110c should be sealed so as to prevent the electrolyte 150 from leaking out of the photoelectric cells. The electrolyte inlets 110a, 110b and 110c may be sealed using fillers 170 and/or cap members 160. As the number of electrolyte inlets is increased, the number of seals that should be made is increased. The increased number of seals results in a higher likelihood that defects that may be formed, thereby reducing product reliability. In addition, since holes needs to be made through the light receiving substrate 100 so as to form electrolyte inlets, as the number of the electrolyte inlets is increased, manufacturing cost and time of the photoelectric conversion module is further increased. According to the present embodiment, since the number of the electrolyte inlets may be reduced by half of that in a typical case, product reliability may be improved, and manufacturing cost and time of the photoelectric conversion module 100 may be reduced.

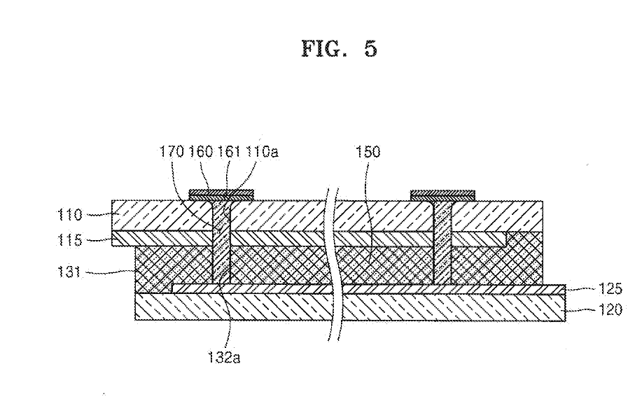

FIG. 5 is a cross-sectional view of the photoelectric conversion module 100 taken along a line V-V′ of FIG. 3. When the electrolyte 150 is filled into the neighboring photoelectric cells S1 and S2 respectively through the electrolyte inlets 110a, 110b, and 110c, as shown in FIG. 4, the neighboring photoelectric cells S1 and S2 need to be sealed. Vias 132a, 132b, and 132c of the sealing members 130 correspond to the electrolyte inlets 110a, 110b, and 110c and are filled with the filler 170. When the filler 170 is a liquid, the filler 170 may then be hardened to separate the neighboring photoelectric cells, for example, S1 and S2. In addition, the electrolyte inlet 110a is also filled with the filler 170. When the filler 170 is a liquid, the filler 170 may then be hardened so as prevent (or protect) the electrolyte 150 from leaking.

As used herein, a via is a pathway, opening, or conduit. More specifically, a via is a conduit between adjacent photoelectric cells. The via may be filled or unfilled, and remains a via (i.e., it may be identified that a pathway or opening existed) whether or not the via is filled or unfilled.

As used herein, the filler 170 could be a plug, i.e., a material having the same viscosity at low and high temperatures. Alternatively, the filler 170 could be a material, such as a polymer or a resin, that is fluid at high temperatures, but relatively solid at low and/or operating temperatures. The filler 170 may be an absorption filler (‘absorption filler 170’). An absorption filler 170 absorbs external moisture so as to prevent external moisture (i.e., undesired moisture) from penetrating into the photoelectric conversion module 100. In addition, the absorption filler 170 prevents (or substantially prevents) the electrolyte 150 from volatizing or leaking.

The absorption filler 170 includes an absorption agent that absorbs moisture, and a resin-based material for containing the absorption agent and for sealing the electrolyte inlets 110a, 110b, and 110c. The resin-based material may be any material for sealing the electrolyte inlets 110a, 110b, and 110c. In addition, a material having a fluidity that varies according to a temperature environment may be selected as the resin-based material. For example, under a high temperature environment, the material has sufficient fluidity so as to be injected through the electrolyte inlets 110a, 110b, and 110c. Under a normal operating temperature environment, the material hardens, sealing the electrolyte inlets 110a, 110b, and 110c. After electrolyte 150 is injected, the absorption filler 170 heated to a high temperature is injected into the electrolyte inlets 110a, 110b, and 110c (by using, for example, a pressurizer such as a syringe), and the absorption filler 170 is cooled to a set or predetermined temperature to be hardened and firmly attached to internal walls of the electrolyte inlets 110a, 110b, and 110c (i.e., cooled to a temperature at which the filler hardens).

Although not illustrated in FIG. 5, the absorption fillers 170 may be poured into the electrolyte inlets 110a, 110b, and 110c and spread out between the light receiving substrate 110 and the opposite substrate 120. That is, the absorption filler 170 may have a shape (“⊥”) including a first portion in the electrolyte inlets 110a, 110b, and 110c, and a second portion extending from the first portion in radial directions between the light receiving substrate 110 and the opposite substrate 120. As such, since the absorption filler 170 is spread between the light receiving substrate 110 and the opposite substrate 120, an adhesive strength of the absorption fillers 170 is determined by an adhesive area of the absorption filler 170, and is strengthened when the adhesive area is increased, thereby effectively preventing the electrolyte 150 from leaking.

The electrolyte inlets 110a, 110b, and 110c may be further sealed by using cap members 160. The cap members 160 may be formed of a material through which harmful components such as oxygen and moisture do not penetrate. For example, the cap members 160 may be formed of a glass film or a metal film. The cap members 160 may be adhered to peripheral portions of the electrolyte inlets 110a, 110b, and 110c by using adhesive agents 161. A resin-based film may be used as the adhesive agent 161. The cap members 160 together with the filler 170 in the electrolyte inlets 110a, 110b, and 110c may doubly seal the electrolyte inlets 110a, 110b, and 110c, thereby effectively preventing the electrolyte 150 from leaking.

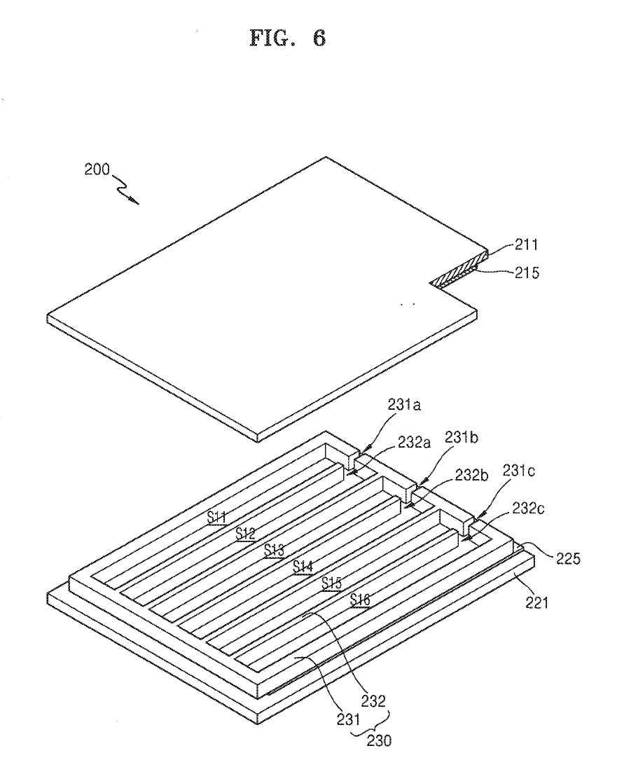

FIG. 6 is an exploded perspective view of a photoelectric conversion module 200 according to another embodiment of the present invention. Referring to FIG. 6, electrolyte inlets 231a, 231b, and 231c are respectively formed at one end of every other sealing member 232 formed in a longitudinal direction between neighboring photoelectric cells. For example, a conduit (i.e. electrolyte inlet) 231a is formed between S11 and S12 so that electrolyte 250 injected through the conduit 231a may be introduced to both of the neighboring photoelectric cells S11 and S12. In addition, the sealing members 232 between every other neighboring photoelectric cell include vias 232a, 232b, and 232c so that a fluid may flow between the neighboring photoelectric cells. For example, a conduit 231a and via 232a are both formed between S11 and S12, allowing an electrolyte to be injected into the conduit and flow between S11 and S12. Thus, in some embodiments, only three electrolyte inlets 231a, 231b, and 231c are formed for the six photoelectric cells S11, S12, S13, S14, S15, and S16. According to the present embodiment, the number of electrolyte inlets may be a quarter of the number of electrolyte inlets in a Comparative Example, wherein 12 electrolyte inlets are respectively formed in photoelectric cells.

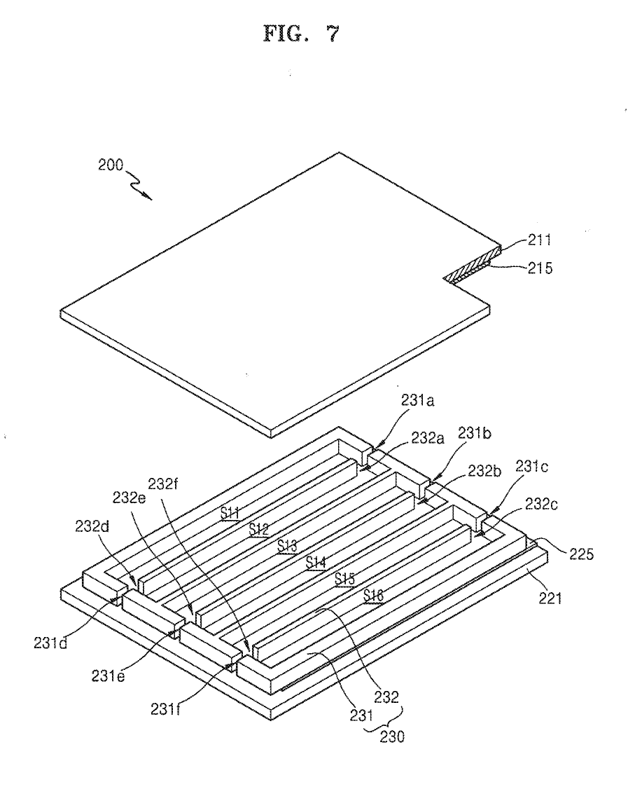

Alternatively, as shown in FIG. 7, electrolyte inlets 231a, 231b, 231c, 231d, 231e, and 231f may be formed at both ends of each sealing member 230 of the photoelectric conversion module 200. Accordingly, the number of electrolyte inlets may be half of the number of electrolyte inlets in a Comparative Example, wherein 12 electrolyte inlets are respectively formed in photoelectric cells.

Sealing members 230 formed between a light receiving substrate 210 and an opposite substrate 220 separate the plurality of photoelectric cells S11, S12, S13, S14, S15, and S16 while maintaining a given distance between each of the cells and the substrates. The sealing members 230 may be formed of glass frit, a resin material, or the like. Examples of the resin material may include a thermosetting resin such as epoxy, a photocurable resin such as ultra violet (UV) hardening epoxy, and a thermo film formed of a thermosetting resin. A thermo film formed of a thermosetting resin may be formed of an ethylene meta acrylic acid copolymer ionomer, a modified polyolefin, or the like. In this case, the thermo film may be disposed between the light receiving substrate 210 and the opposite substrate 220, and then the light receiving substrate 210 and the opposite substrate 220 may be pressurized by applying a set or predetermined amount of heat and pressure thereto to form the sealing members 230.

According to the present embodiment, since the electrolyte inlets 231a, 231b, and 231c are not formed in the light receiving substrate 210 or the opposite substrate 220, a separate step of making a hole in the light receiving substrate 210 or the opposite substrate 220 does not have to be performed. Instead, according to the present embodiment, the sealing members 230 may be simply formed having the electrolyte inlets 231a, 231b, and 231c and the vias 232a, 232b, and 232c, thereby simplifying the manufacturing process. The electrolyte 250 may be injected using any suitable method.

With reference to FIG. 6, an example of a method of injecting the electrolyte 250 will now be described. A substrate assembly including the light receiving substrate 210 and the opposite substrate 220 is formed. The side of the light receiving substrate 210 where the electrolyte inlets 231a, 231b, and 231c are formed may be directed upwards. The electrolyte 250 may then be injected through the electrolyte inlets 231a, 231b and 231c by using a special pressurizing installment for injecting the electrolyte 250.

With reference to FIG. 6, another example of the method of injecting the electrolyte 250 will now be described. In one embodiment, a substrate assembly including the light receiving substrate 210 and the opposite substrate 220 is immersed in a bath filled with an electrolyte while a side of the light receiving substrate 210 where the electrolyte inlets 231a, 231b, and 231c are formed may be directed downwards. A vacuum pressure or a negative pressure is applied to a sealed chamber surrounding the bath and the substrate assembly by using a negative pressure installment, and then the chamber is opened to an atmosphere pressure. Thus, the electrolyte filled in the bath may be injected into the substrate assembly due to a pressure difference between inside and outside of the substrate assembly.

With reference to FIG. 7, another example of the method of injecting the electrolyte 250 will now be described. A substrate assembly is erected so that the electrolyte inlets 231a, 231b, and 231c at one side of the substrate assembly may be directed upwards, and electrolyte inlets 231d, 231e, and 231f at another side may be directed downwards. An electrolyte is injected by applying a negative pressure to the electrolyte inlets 231a, 231b, and 231c and applying a positive pressure to the electrolyte inlets 231d, 231e, and 231f. Then, the electrolyte inlets 231a, 231b, and 231c are sealed, the substrate assembly is turned upside down, and then the electrolyte inlets 231d, 231e, and 231f are sealed.

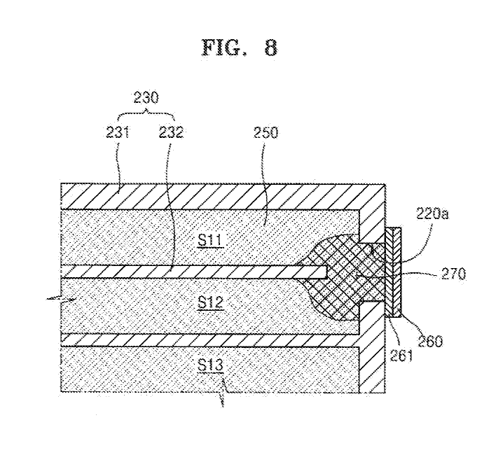

Electrolyte inlets are sealed as follows. Referring to FIG. 8, the electrolyte inlets 231a, 231b, and 231c, and the vias 232a, 232b, and 232c are filled with filler 270, and, if liquid, the filler 270 is hardened to spatially separate the neighboring photoelectric cells, for example, S11 and S12, thus preventing (or protecting) the electrolyte 250 from leaking if sealed properly. According to the present embodiment, the filler 270 may be an absorption filler. The filler 270 may be formed of glass frit.

After the filler 270 is installed, the electrolyte inlets may be sealed by cap members 260. For example, the cap members 260 may be attached onto the filler 270 by interposing seals 261 between the cap members 260 and the filler 270. The cap members 260 may be a glass plate or a metal film, and may prevent external harmful components such as oxygen or moisture from penetrating into the photoelectric conversion module 200.

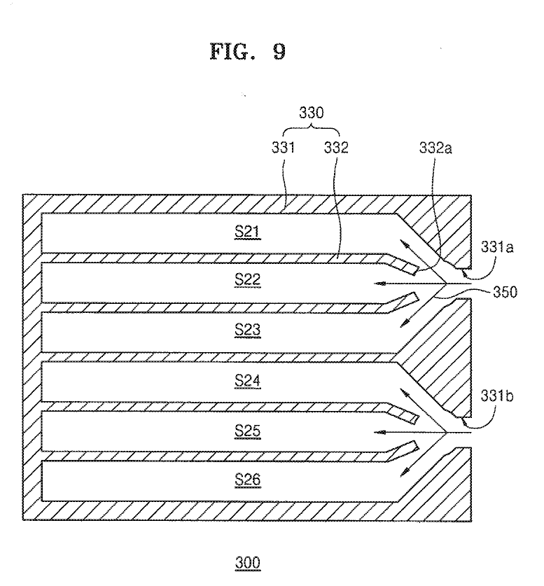

FIG. 9 is a schematic plan view showing spreading directions of an electrolyte 350 injected through electrolyte inlets 331a and 331b in a photoelectric conversion module 300, according to yet another embodiment of the present invention. Referring to FIG. 9, the electrolyte inlets 331a and 331b are respectively formed at one side of three neighboring photoelectric cells S21, S22, and S23 so that the electrolyte 350 injected through electrolyte inlets 331a and 331b formed at one side of the photoelectric conversion module 300 may be introduced to the three neighboring photoelectric cells S21, S22 and S23 and S24, S25, and S26, respectively. In addition, sealing members 332 separating neighboring photoelectric cells, for example S21, S22, and S23, include a via 332a, allowing a fluid to flow between neighboring photoelectric cells S21, S22, and S23. Thus, only two electrolyte inlets 331a and 331b may be formed for the six photoelectric cells S21, S22, S23, S24, S25, and S26. According to the present embodiment, the number of electrolyte inlets may be a sixth of the number of electrolyte inlets in a Comparative Example, where 12 electrolyte inlets are respectively formed in photoelectric cells.

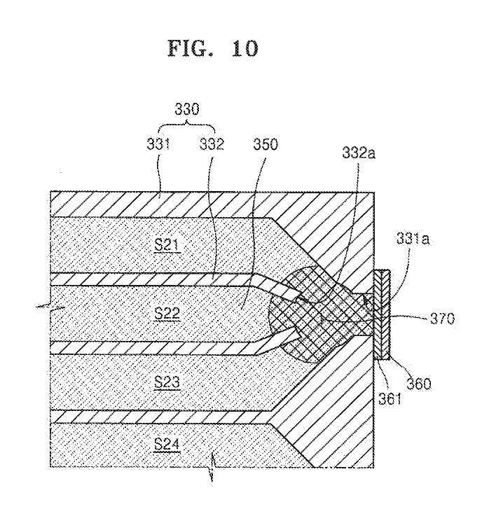

FIG. 10 is a plan view showing an electrolyte inlet 331a and via 332a of the photoelectric conversion module 300 of FIG. 9 that are sealed. Sealing the electrolyte inlet 331a and the via 332a is understood with reference to FIG. 8 as described above.

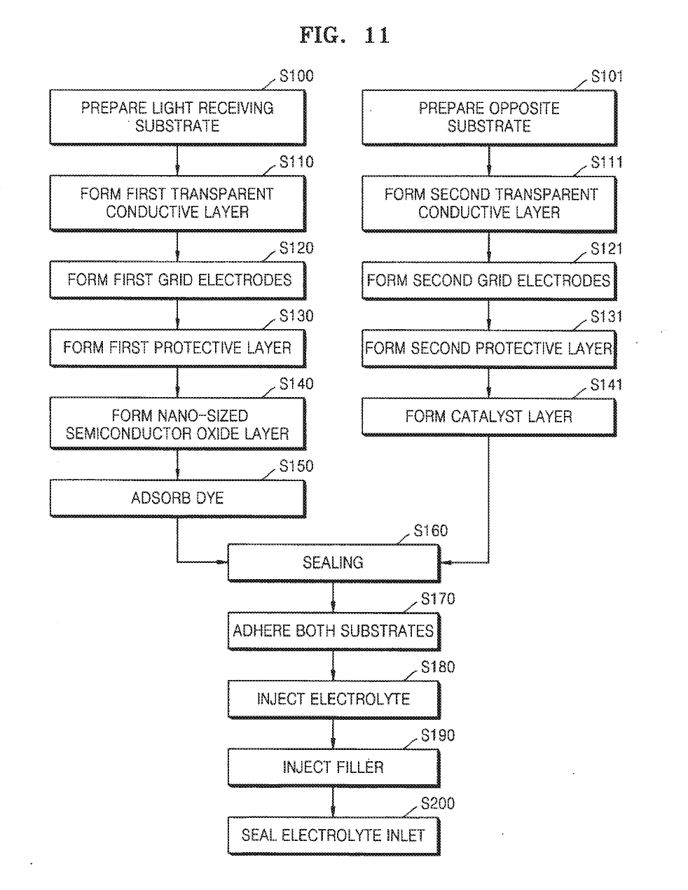

FIG. 11 is a flow chart showing a method of manufacturing a photoelectric conversion module according to an embodiment of the present invention. The photoelectrode 111 and the semiconductor oxide layer 113 are formed on the light receiving substrate 110 or 210 (Steps S100 to S150). The opposite electrode 121 and the catalyst layer 123 are formed on the opposite substrate 120 (Steps S101 to S141). The light receiving substrate 110 and the opposite substrate 120 are adhered and sealed to each other (Steps S160 and S170). The electrolyte 150, 250, or 350 is injected into the photoelectric cells S1, S2, S3, S4, S5, and S6, or S11, S12, S13, S14, S15, and S16, or S21, S22, S23, S24, S25, and S26 through the conduits (i.e., electrolyte inlets) 110a, 110b, and 110c, or 220a, 220b, and 220c, or 331a and 331b (Step S180). Filler 150, 250, or 350 is then injected into the conduits (i.e., electrolyte inlets) 110a, 110b, and 110c, or 220a, 220b, and 220c, or 331a and 331b (Step S190) to seal the conduits 110a, 110b, and 110c, or 220a, 220b, and 220c, or 331a and 331b (Step S200), thereby completing the manufacture of a solar cell.

A method of forming the photoelectrode 111 on the light receiving substrate 110 will now be described. First, a first transparent conductive layer formed of a material such as ITO or FTO is formed on the light receiving substrate 110, which may be a transparent glass (Step S110). First parallel grid electrodes formed of Ag or Al are formed in one direction on the first transparent conductive layer (S120). The first grid electrodes may be formed in a stripe pattern, but the arrangement of the first grid electrodes may be modified in various ways. A first protective layer for protecting the first grid electrodes may be formed on the first grid electrodes (Step S130). A nano-sized semiconductor oxide layer is formed on the first transparent conductive layer and the first protective layer (Step S140). The nano-sized semiconductor oxide layer may be a TiO₂ layer, an SnO₂ layer, or a ZnO layer. Dye molecules are adsorbed onto the nano-sized semiconductor oxide layer (Step S150). The dye molecules are adsorbed onto the nano-sized semiconductor oxide layer by immersing the nano-sized semiconductor oxide layer of the light receiving substrate 110 in a dye.

A method of forming the opposite electrode 121 on the opposite substrate 120 will now be described. First, a second transparent conductive layer formed of a material such as ITO or FTO is formed on the opposite substrate 120, which may be a transparent glass (Step S111). Second parallel grid electrodes formed of Ag or Al are formed in one direction on the second transparent conductive layer (Step S121). The second grid electrodes may be formed in a stripe pattern, but the arrangement of the second grid electrodes may be modified in various ways. A second protective layer for protecting the second grid electrodes is formed on the second grid electrodes (Step S131). The catalyst layer 123 is formed on the second grid electrodes and the second protective layer (Step S141). The catalyst layer 123 may be a platinum (Pt) layer or a carbon (C) film.

The above-described methods of forming the photoelectrode 111 on the light receiving substrate 110 and forming the opposite electrode 121 on the opposite substrate 120 are just exemplary. One of ordinary skill in the art may use other methods of forming a photoelectrode and an opposite electrode that are modifications of the present disclosure by one of ordinary skill in the art. These methods and resulting structures are within the scope of the one or more of the above embodiments of the present invention.

It should be understood that the exemplary embodiments described therein should be considered in a descriptive sense only and not for purposes of limitation. Descriptions of features or aspects within each embodiment should typically be considered as available for other similar features or aspects in other embodiments.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A photoelectric conversion module comprising:
a first photoelectric cell and a second photoelectric cell, each of the photoelectric cells comprising a photoelectrode, a counter electrode facing the photoelectrode, and a semiconductor layer on the photoelectrode and onto which a photosensitive dye is adsorbed; and
a first sealing member extending along a first direction between the first photoelectric cell and the second photoelectric cell, the first sealing member defining a first via between the first photoelectric cell and the second photoelectric cell.

2. The photoelectric conversion module of claim 1, further comprising a conduit, the conduit corresponding and adjacent to the first via.

3. The photoelectric conversion module of claim 2, further comprising a filler in the conduit to seal the conduit.

4. The photoelectric conversion module of claim 3, further comprising a cap adjacent to the filler and configured to form a double sealing structure to seal the conduit.

5. The photoelectric conversion module of claim 2, further comprising a first substrate and a second substrate, the first and second photoelectric cells being between the first substrate and the second substrate, wherein the conduit extends through one of the first substrate or the second substrate along a second direction crossing the first direction.

6. The photoelectric conversion module of claim 2, further comprising a sealing frame surrounding the photoelectric cells, wherein the conduit extends through the sealing frame to communicate with the first via.

7. The photoelectric conversion module of claim 2, wherein the first via is at a first end of the first and second photoelectric cells, the first sealing member defines a second via at a second end of the first and second photoelectric cells, the conduit is at the first end of the first and second photoelectric cells and a second conduit is at a second end of the first and second photoelectric cells corresponding and adjacent to the second via.

8. The photoelectric conversion module of claim 1, further comprising a third photoelectric cell, and a second sealing member extending along the first direction between the second photoelectric cell and the third photoelectric cell, the second sealing member defining a second via between the second photoelectric cell and the third photoelectric cell.

9. The photoelectric conversion module of claim 8, further comprising a conduit corresponding and adjacent to the first and second vias.

10. The photoelectric conversion module of claim 1, further comprising a filler in the first via, the filler configured to physically block the first photoelectric cell from the second photoelectric cell.

11. The photoelectric conversion module of claim 10, further comprising a cap adjacent to the filler and configured to seal the solar cell.

12. The photoelectric conversion module of claim 11, further comprising a conduit, the conduit corresponding and adjacent to the first via, wherein the filler and the cap are configured to physically block the conduit.

13. A method of forming a photoelectric conversion module, the method comprising:
forming a photoelectrode on a first substrate;
forming a semiconductor layer on the photoelectrode;
adsorbing a photosensitive dye on the semiconductor layer;
forming an electrode on a second substrate;
forming a catalyst layer on the electrode;
providing a sealing member extending along a first direction between a first photoelectric cell and a second photoelectric cell;
providing a via in the sealing member between the first photoelectric cell and the second photoelectric cell;
adhering the first substrate to the second substrate;
providing a conduit to correspond and be adjacent to the via;
filling the first photoelectric cell and second photoelectric cell with an electrolyte through the conduit and the via;
providing a filler in the via to physically block the first photoelectric cell from the second photoelectric cell; and
sealing the conduit.

14. The method of forming the photoelectric conversion module of claim 13, wherein the sealing the conduit comprises providing the filler to fill the conduit.

15. The method of forming the photoelectric conversion module of claim 13, wherein the sealing the conduit comprises providing a cap and affixing the cap over the conduit.

16. The method of forming the photoelectric conversion module of claim 15, wherein the affixing of the cap comprises providing an adhering agent to adhere the cap over the conduit.

17. The method of forming the photoelectric conversion module of claim 13, wherein the providing of the conduit comprises forming the conduit in the first substrate or the second substrate to extend along a second direction crossing the first direction.

18. The method of forming the photoelectric conversion module of claim 17, wherein the providing of the via in the sealing member comprises forming the via through the sealing member along a third direction crossing the first direction and the second direction.

19. The method of forming the photoelectric conversion module of claim 13, further comprising forming a sealing frame to surround the photoelectric cells, wherein the providing of the conduit comprises forming the conduit through the sealing frame to communicate with the via.

20. The method of forming the photoelectric conversion module of claim 13, wherein the providing of the via comprises providing a first via at a first end of the first and second photoelectric cells and providing a second via at a second end of the first and second photoelectric cells, and the proving of the conduit comprises providing a first conduit at the first end of the first and second photoelectric cells and providing a second conduit at the second end of the first and second photoelectric cells, the second conduit corresponding and adjacent to the second via.
